(19) United States
(12) Patent Application Publication
(10) Pub. No.: US 2020/0312484 A1
(43) Pub. Date: Oct. 1, 2020

(54) DIELECTRIC FILM, ELECTRONIC COMPONENT, THIN FILM CAPACITOR, AND ELECTRONIC CIRCUIT BOARD

(71) Applicant: TDK Corporation, Tokyo (JP)

(72) Inventors: Shirou OOTSUKI, Tokyo (JP); Aiko TAKAHASHI, Tokyo (JP); Wakiko SATO, Tokyo (JP)

(73) Assignee: TDK Corporation, Tokyo (JP)

(21) Appl. No.: 16/819,073

(22) Filed: Mar. 14, 2020

(30) Foreign Application Priority Data
Mar. 25, 2019 (JP) 2019-057102
Mar. 25, 2019 (JP) 2019-057108
Sep. 30, 2019 (JP) 2019-178855

(51) Int. Cl. H01B 3/12; H01G 4/33; H01G 4/12; H05K 1/18; C01G 29/00

(52) U.S. Cl. CPC H01B 3/12; H01G 4/33; H01G 4/1227; H05K 1/185; C01P 2002/50; H05K 2201/10015; C01P 2002/34; C01P 2006/40; C01G 29/006

(57) ABSTRACT

This dielectric film is a dielectric film comprising an oxide having a perovskite structure. The oxide comprises (1) Bi, Na and Ti, (2) at least one of Ba and Ca, and (3) at least one element Ln selected from the group consisting of La, Ce, Pr, Nd, Sm, Eu, Gd, Tb, Dy, Ho, Yb and Y. When ratios of the numbers of atoms of Bi, Ba and Ca to the total of the numbers of atoms of Bi, Na, Ba and Ca in the oxide are represented by X_{Bi}, X_{Ba} and X_{Ca}, respectively, the ratios satisfy 0.2≤X_{Bi}/(X_{Ba}+X_{Ca})≤5.

### TECHNICAL FIELD

The present invention relates to a dielectric film, an electronic component, a thin film capacitor and an electronic circuit board.

### BACKGROUND

In an electronic device, the mounting space allowed for an electronic component tends to be reduced with downsizing of electronic devices. A capacitor (referred to as a “condenser” in many cases in Japan) is an electronic component mounted in many electronic devices, and also for it, downsizing and thinning are inevitable. In a thin film capacitor, a substrate, a dielectric film, an insulating film, etc. are thin as compared with those in a multilayer ceramic capacitor by a conventional thick film method, so that further thinning and profile lowering are possible. On that account, the thin film capacitor is expected as an electronic component to be mounted in a low-profile and small space. Moreover, a capacitor embedded in an electronic component board has been developed in recent years.

In many thin film capacitors, the capacitance is small as compared with that in conventional multilayer ceramic capacitors. As one method to improve the capacitance, there is a method of decreasing a film thickness of the dielectric film. However, if the film thickness of the dielectric film is decreased, a DC electric field intensity applied to the dielectric becomes large even when the DC voltages applied to both ends of the dielectric film during actual use are the same. Ferroelectrics such as BaTiO₃ have so-called DC bias characteristics that the dielectric constant decreases as the DC electric field intensity increases, and therefore, even if the film thickness is decreased, the capacitance cannot be improved.

In addition, if the DC electric field intensity is increased by decreasing the film thickness of the dielectric film, the risk of device destruction due to the electric field increases, so that high withstand voltage characteristics are also required.

In Patent Literature 1, it is disclosed that DC bias characteristics are enhanced by using a tungsten bronze type composite oxide comprising K, Sr, Mg and Nb in a dielectric film.

In Patent Literature 2, it is disclosed that a high dielectric constant and high withstand voltage characteristics are realized by providing a dielectric thin film formed by a hydrothermal synthesis method and represented by Ba₁₋ₓCaₓZr_{y}Ti_{1-y}O₃ (wherein 0<x<0.2, 0<y<1) on a conductive substrate having a Ti element on its surface.

### CITATION LIST

### Patent Literature

Patent Literature 1: Japanese Unexamined Patent Publication No. 2000-49045
Patent Literature 2: Japanese Unexamined Patent Publication No. 2000-173349

### SUMMARY

In Patent Literatures 1 and 2, however, the withstand voltage characteristics and the DC bias characteristics are not compatible with each other.

The present invention has been made in order to solve the above problem, and it is an object of the present invention to provide a dielectric film in which the DC bias characteristics and the withstand voltage characteristics are compatible with each other, an electronic component, a thin film capacitor and an electronic circuit board.

The dielectric film according to one aspect of the present invention is a dielectric film comprising an oxide having a perovskite structure. Here, the oxide comprises (1) Bi, Na and Ti, (2) at least one of Ba and Ca, and (3) at least one element Ln selected from the group consisting of La, Ce, Pr, Nd, Sm, Eu, Gd, Tb, Dy, Ho, Yb and Y. When ratios of the numbers of atoms of Bi, Ba and Ca to the total of the numbers of atoms of Bi, Na, Ba and Ca in the oxide are represented by X_{Bi}, X_{Ba} and X_{Ca}, respectively, the ratios satisfy 0.2≤X_{Bi}/(X_{Ba}+X_{Ca})≤5.

Here, when a ratio of the number of atoms of Na to the total of the numbers of atoms of Bi, Na, Ba and Ca in the oxide is represented by X_{Na}, the ratio can satisfy 0.9X_{Bi}≤X_{Na}≤1.1X_{Bi}.

In the oxide, a ratio of the number of atoms of Ti to the total of the numbers of atoms of Bi, Na, Ba and Ca can be 80% or more and 120% or less.

In the oxide, a ratio of the number of atoms of Ln to the total of the numbers of atoms of Bi, Na, Ba and Ca can be 0.5 to 20%.

The dielectric film according to another aspect of the present invention is a dielectric film comprising an oxide having a perovskite structure. Here, the oxide comprises (1) Bi, K and Ti, (2) at least one selected from the group consisting of Ba, Sr and Ca, and (3) at least one element Ln selected from the group consisting of La, Ce, Pr, Nd, Sm, Eu, Gd, Tb, Dy, Ho, Yb and Y. When ratios of the numbers of atoms of Bi, Ba, Sr and Ca to the total of the numbers of atoms of Bi, K, Ba, Sr and Ca in the oxide are represented by X_{Bi}, X_{Ba}, Xₛᵣ and X_{Ca}, respectively, the ratios satisfy 0.2≤X_{Bi}/(X_{Ba}+X_{Sr}+X_{Ca})≤5.

Here, when a ratio of the number of atoms of K to the total of the numbers of atoms of Bi, K, Ba, Sr and Ca in the oxide is represented by X_{K}, the ratio can satisfy 0.9X_{Bi}≤X_{K}≤1.1X_{Bi}.

In the oxide, a ratio of the number of atoms of Ti to the total of the numbers of atoms of Bi, K, Ba, Sr and Ca can be 80% or more and 120% or less.

In the oxide, a ratio of the number of atoms of Ln to the total of the numbers of atoms of Bi, K, Ba, Sr and Ca can be 0.5 to 20%.

The electronic component according to the present invention comprises the aforesaid dielectric film.

The thin film capacitor according to the present invention comprises the aforesaid dielectric film.

The electronic circuit board according to one aspect of the present invention comprises the aforesaid dielectric film.

The electronic circuit board according to one aspect of the present invention comprises the aforesaid electronic component.

The electronic circuit board according to one aspect of the present invention comprises the aforesaid thin film capacitor.

According to the present invention, a thin film capacitor in which DC bias characteristics and withstand voltage characteristics are compatible with each other, etc. are provided.

### BRIEF DESCRIPTION OF THE DRAWINGS

FIG. 1 is a schematic sectional view of a thin film capacitor according to one example of an electronic component according to the present embodiment.

FIG. 2A is a schematic sectional view of an electronic circuit board according to one embodiment of the present invention.

FIG. 2B is an enlarged view of a part 90A shown in FIG. 2A.

### DETAILED DESCRIPTION

A first embodiment of the present invention will be described in detail hereinafter.

(Dielectric Film)

The dielectric film according to the first embodiment of the present invention comprises an oxide having a perovskite structure.

This oxide comprises the following (1) to (3).
(1) Bi, Na and Ti,
(2) at least one of Ba and Ca, and
(3) at least one element Ln selected from the group consisting of La, Ce, Pr, Nd, Sm, Eu, Gd, Tb, Dy, Ho, Yb and Y.

When ratios of the numbers of atoms of Bi, Ba and Ca to the total of the numbers of atoms of Bi, Na, Ba and Ca in this oxide are represented by X_{Bi}, X_{Ba} and X_{Ca}, respectively, the ratios satisfy
0.2≤X_{Bi}/(X_{Ba}+X_{Ca})≤5. As the upper limit, preferable is 4.5 or less, and more preferable is 4 or less.

When a ratio of the number of atoms of Na to the total of the numbers of atoms of Bi, Na, Ba and Ca in this oxide is represented by X_{Na}, the ratio can satisfy 0.9X_{Bi}≤X_{Na}≤1.1X_{Bi}. Preferably, the ratio satisfies 0.95X_{Bi}≤X_{Na}≤1.05X_{Bi}. Preferably, the ratio satisfies 0.98X_{Bi}≤X_{Na}≤1.02X_{Bi}, and the ratio may satisfy X_{Na}=X_{Bi}.

In this oxide, a ratio of the number of atoms of Ti to the total of the numbers of atoms of Bi, Na, Ba and Ca can be 80% or more and 120% or less. The ratio of the number of atoms of Ti may be 85% or more, may be 90% or more, may be 95% or more, may be 115% or less, may be 110% or less, and may be 105% or less.

In this oxide, a ratio of the number of atoms of Ln to the total of the numbers of atoms of Bi, Na, Ba and Ca can be 0.5 to 20%. It is preferable that the ratio of the number of atoms of this Ln be 1 to 15%.

In this oxide, a ratio of the total of the numbers of atoms of Ba and Ca to the total of the numbers of atoms of Bi, Na, Ba and Ca can be set at 10 to 70%.

This oxide only needs to comprise at least one of Ba and Ca, but may comprise both of Ba and Ca. It is preferable for this oxide not to comprise Sr.

Of the elements Ln, La is preferable.

The perovskite structure is a crystal structure generally represented by ABX₃. A cation of the A site is located at the vertex of a unit lattice of a hexahedron, a cation of the B site is located at the body center of this unit lattice, and an anion of the X site is located at the face center of this unit lattice. In the present invention, cations such as Ba²⁺, Ca²⁺, Bi³⁺, Na⁺ and Ln ion (divalent, or combination of monovalent and trivalent) enter the A site, tetravalent cations such as Ti⁴⁺ ion enter the B site, and divalent anions such as O²⁻ ion enter the X site. The Ln ion can also enter the B site.

The oxide may occupy 70 mass % or more of the dielectric film, may occupy 80 mass % or more, 90 mass % or more, 95 mass % or more, 99 mass % or more, or may occupy 100 mass %.

The thickness of the dielectric film is not limited, but for example, the thickness can be set at 10 nm to 2000 nm, and it is preferable that the thickness be 50 nm to 1000 nm.

Such a dielectric film is excellent in both the DC bias characteristics and the withstand voltage characteristics. Although the reason for this is not clear, the present inventors think that it is as follows.

Development of a dielectric constant in an oxide having a perovskite-type crystal structure is attributed to displacement of an ion of each element relative to an AC voltage, and when the voltage is high, displacement of an ion is saturated, whereby lowering of a dielectric constant due to DC bias takes place. The present inventors think that for the displacement of an ion of the perovskite-type crystal structure, a combination of bonds between ions of the A site and the B site and an ion of oxygen is important, and by satisfying 0.2≤X_{Bi}/(X_{Ba}+X_{Ca})≤5 in the case where the perovskite-type crystal structure containing Bi, Na and Ti comprises at least one or more selected from Ba and Ca, the degree of freedom of each bond increases, whereby the magnitude of DC bias at which the displacement of an ion is saturated increases.

The present inventors think that the Curie point of the oxide of the perovskite structure containing Bi, Na and Ti is about 300° C., and when at least one or more selected from Ba and Ca is comprised, the Curie point of the perovskite-type oxide containing Bi, Na and Ti comes close to the vicinity of room temperature, whereby the absolute value of the dielectric constant increases, so that the dielectric constant during application of DC bias also increases.

The present inventors think that the valences of ions of La, Ce, Pr, Nd, Sm, Eu, Gd, Tb, Dy, Ho, Yb and Y take a plurality of valences including +trivalence, and the ions can enter both the AB sites of the perovskite structure, and therefore, charge transfer caused by defects such as oxygen defect is suppressed, whereby charge concentration decreases, and improvement in withstand voltage is carried out.

The dielectric film according to the present embodiment may comprise, in addition to the oxide, trace amounts of impurities, sub-components, etc. within a range where the effect of the present invention is exerted. Examples of such components include Cr and Mo.

The dielectric film may further comprise, for example, at least one rare earth element selected from the group consisting of Sc (scandium), Y (yttrium), La (lanthanum), Ce (cerium), Pr (praseodymium), Nd (neodymium), Pm (promethium), Sm (samarium), Eu (europium), Gd (gadolinium), Tb (terbium), Dy (dysprosium), Ho (holmium), Er (erbium), Tm (thulium), Yb (ytterbium), and Lu (lutetium). Since the dielectric film further comprises a rare earth element, the DC bias characteristics of the dielectric film sometimes improve.

A second embodiment of the present invention will be described in detail hereinafter.

(Dielectric Film)

The dielectric film according to the second embodiment of the present invention comprises an oxide having a perovskite structure.

This oxide comprises the following (1) to (3).
(1) Bi, K and Ti,
(2) at least one selected from the group consisting of Ba, Sr and Ca, and
(3) at least one element Ln selected from the group consisting of La, Ce, Pr, Nd, Sm, Eu, Gd, Tb, Dy, Ho, Yb and Y.

When ratios of the numbers of atoms of Bi, Ba, Sr and Ca to the total of the numbers of atoms of Bi, K, Ba, Sr and Ca in this oxide are represented by X_{Bi}, X_{Ba}, X_{Sr} and X_{Ca}, respectively, the ratios satisfy 0.2≤X_{Bi}/(X_{Ba}+X_{Sr}+X_{Ca})≤5. As the upper limit, preferable is 4.5 or less, and more preferable is 4 or less.

When a ratio of the number of atoms of K to the total of the numbers of atoms of Bi, K, Ba, Sr and Ca in this oxide is represented by X_{K}, the ratio can satisfy 0.9X_{Bi}≤X_{K}≤1.1X_{Bi}. Preferably, the ratio satisfies 0.95X_{Bi}≤X_{K}≤1.05X_{Bi}. Preferably, the ratio satisfies 0.98X_{Bi}≤X_{K}≤1.02X_{Bi}, and the ratio may satisfy X_{K}=X_{Bi}.

In this oxide, a ratio of the number of atoms of Ti to the total of the numbers of atoms of Bi, K, Ba, Sr and Ca can be 80% or more and 120% or less. The ratio of the number of atoms of the Ti may be 85% or more, may be 90% or more, may be 95% or more, may be 115% or less, may be 110% or less, and may be 105% or less.

In this oxide, a ratio of the number of atoms of Ln to the total of the numbers of atoms of Bi, K, Ba, Sr and Ca can be 0.5 to 20%. It is preferable that the ratio of the number of atoms of this Ln be 1 to 15%.

In this oxide, a ratio of the total of the numbers of atoms of Ba, Sr and Ca to the total of the numbers of atoms of Bi, K, Ba, Sr and Ca can be set at 10 to 70%.

This oxide only needs to comprise at least one of Ba, Sr and Ca, but may comprise a combination of Ba and Sr, a combination of Ba and Ca, and a combination of Sr and Ca, and may contain a combination of all of Ba, Sr and Ca.

Of the elements Ln, La is preferable.

The perovskite structure is a crystal structure generally represented by ABX₃. A cation of the A site is located at the vertex of a unit lattice of a hexahedron, a cation of the B site is located at the body center of this unit lattice, and an anion of the X site is located at the face center of this unit lattice. In the present invention, cations such as Ba²⁺, Sr²⁺, Ca²⁺, Bi³⁺, K⁺ and Ln ion (divalent, or combination of monovalent and trivalent) enter the A site, tetravalent cations such as Ti⁴⁺ ion enter the B site, and divalent anions such as O²⁻ ion enter the X site. The Ln ion can also enter the B site.

The oxide may occupy 70 mass % or more of the dielectric film, may occupy 80 mass % or more, 90 mass % or more, 95 mass % or more, 99 mass % or more, or may occupy 100 mass %.

The thickness of the dielectric film is not limited, but for example, the thickness can be set at 10 nm to 2000 nm, and it is preferable that the thickness be 50 nm to 1000 nm.

Such a dielectric film is excellent in both the DC bias characteristics and the withstand voltage characteristics. Although the reason for this is not clear, the present inventors think that it is as follows.

Development of a dielectric constant in an oxide having a perovskite-type crystal structure is attributed to displacement of an ion of each element relative to an AC voltage, and when the voltage is high, displacement of an ion is saturated, whereby lowering of a dielectric constant due to DC bias takes place. The present inventors think that for the displacement of an ion of the perovskite-type crystal structure, a combination of bonds between ions of the A site and the B site and an ion of oxygen is important, and by satisfying 0.25≤X_{Bi}/(X_{Ba}+X_{Sr}+X_{Ca})≤5 in the case where the perovskite-type crystal structure containing Bi, K and Ti comprises at least one or more selected from Ba, Sr and Ca, the degree of freedom of each bond increases, whereby the magnitude of DC bias at which the displacement of an ion is saturated increases.

The present inventors think that the Curie point of the oxide of the perovskite structure containing Bi, K and Ti is about 300° C., and when at least one or more selected from Ba, Sr and Ca is comprised, the Curie point of the perovskite-type oxide containing Bi, K and Ti comes close to the vicinity of room temperature, whereby the absolute value of a dielectric constant increases, so that the dielectric constant during application of DC bias also increases.

The present inventors think that the valences of ions of La, Ce, Pr, Nd, Sm, Eu, Gd, Tb, Dy, Ho, Yb and Y take a plurality of valences including +trivalence, and the ions can enter both the AB sites of the perovskite structure, and therefore, charge transfer caused by defects such as oxygen defect is suppressed, whereby charge concentration decreases, and improvement in withstand voltage is carried out.

The dielectric film according to the present embodiment may comprise, in addition to the oxide, trace amounts of impurities, sub-components, etc. within a range where the effect of the present invention is exerted. Examples of such components include Cr and Mo.

The dielectric film may further comprise, for example, at least one rare earth element selected from the group consisting of Sc (scandium), Y (yttrium), La (lanthanum), Ce (cerium), Pr (praseodymium), Nd (neodymium), Pm (promethium), Sm (samarium), Eu (europium), Gd (gadolinium), Tb (terbium), Dy (dysprosium), Ho (holmium), Er (erbium), Tm (thulium), Yb (ytterbium), and Lu (lutetium). Since the dielectric film further comprises a rare earth element, the DC bias characteristics of the dielectric film sometimes improve.

(Process for Producing Dielectric Film)

The above dielectric film can be produced by various processes. Examples of known deposition methods include vacuum deposition method, sputtering method, pulsed laser deposition (PLD), metal organic chemical vapor deposition (MOCVD), metal organic decomposition (MOD), sol-gel method and chemical solution deposition (CSD).

Specifically, the ratios of metallic elements in a raw material composition used in each deposition method only need to be set in the aforesaid range. In the raw materials (deposition materials, various target materials, organometallic materials, etc.) used in the deposition, trace amounts of impurities, sub-components, etc. are sometimes comprised, but there is no particular problem as long as desired dielectric characteristics are obtained.

For example, when a sputtering method is used, an oxide target having the aforesaid metal composition is prepared first. Specifically, powders of compounds containing metals, such as carbonates, oxides and hydroxides, are provided, and they are mixed in such a manner that the ratios of the metallic elements are in the aforesaid range, thereby obtaining a mixed powder. It is preferable that the mixing be carried out in water using, for example, a ball mill. Next, the mixed powder is compacted to obtain a compact. The compacting pressure can be set at, for example, 10 to 200 MPa.

Thereafter, the resulting compact is fired to obtain a fired product. As the firing conditions, the retention temperature can be set at 900 to 1300° C., the retention time at the temperature can be set at 1 to 10 hours, and the atmosphere can be an oxidizing atmosphere such as air. Finally, the resulting fired product is processed into a disc shape, thereby obtaining a sputtering target.

Next, the resulting target is sputtered to form the dielectric film as a deposition film on a substrate. Although the sputtering conditions are not particularly limited, radio frequency (RF) sputtering is preferable, the power can be set at 100 W to 300 W, an oxygen-containing atmosphere is preferable as the atmosphere, particularly an oxygen-containing argon gas atmosphere is preferable, the argon (Ar)/oxygen (O₂) ratio is preferably 1/1 to 5/1, and the substrate temperature can be preferably set at room temperature to 200° C.

After the dielectric film is formed by sputtering, it is also preferable to subject the dielectric film to rapid thermal anneal (RTA). As the conditions to carry out RTA, it is preferable that the atmosphere be an air atmosphere, it is preferable that the temperature rise rate be set at 100° C./min or higher, it is preferable that the annealing time be set at 0.5 to 120 minutes, and it is preferable that the annealing temperature be set at 700° C. or higher and 1000° C. or lower.

(Thin Film Capacitor)

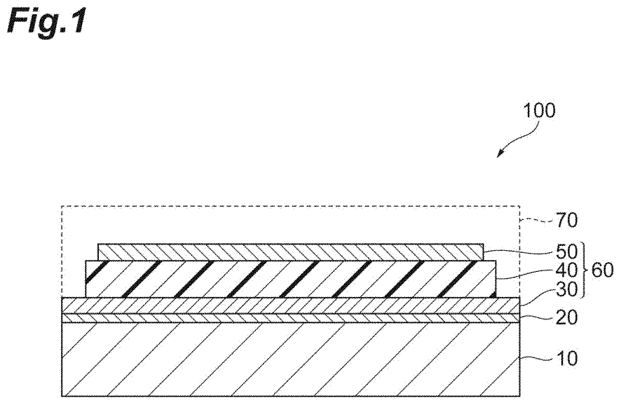

Subsequently, as one example of an electronic component having the dielectric film according to an embodiment of the present invention, a thin film capacitor will be described by reference to FIG. 1.

The thin film capacitor 100 according to an embodiment of the present invention has a substrate 10, an adhesive film 20, a lower electrode 30, a dielectric film 40, and an upper electrode 50 in this order.

(Substrate)

The substrate 10 supports the adhesive film 20, the lower electrode 30, the dielectric film 40 and the upper electrode 50 which are formed on the substrate. The material of the substrate 10 is not particularly limited as long as it is a material having mechanical strength of such an extent as to be able to support the above each layer. Examples of the substrate 10 include substrates of single crystals such as Si single crystal, SiGe single crystal, GaAs single crystal, InP single crystal, SrTiO₃ single crystal, MgO single crystal, LaAlO₃ single crystal, ZrO₂ single crystal, MgAl₂O₄ single crystal and NdGaO₃ single crystal; substrates of ceramic polycrystals such as Al₂O₃ polycrystal, ZnO polycrystal and SiO₂ polycrystal; and substrates of metals selected from Ni, Cu, Ti, W, Mo, Al, Pt and alloys thereof. From the viewpoints of low cost and processability, the Si single crystal substrate is preferable.

The thickness of the substrate 10 can be, for example, 10 μM to 5000 μm. If the thickness is too small, mechanical strength cannot be sometimes secured, and if the thickness is too large, a problem that the substrate cannot contribute to downsizing of an electronic component sometimes occurs.

The electrical resistivity of the substrate 10 varies depending upon the material of the substrate. When the substrate is composed of a material having a low electrical resistivity, leakage of a current to the substrate 10 side sometimes takes place during working of the thin film capacitor and exerts influence on the electrical characteristics of the thin film capacitor. On that account, when the electrical resistivity of the substrate 10 is low, it is preferable that the substrate surface be subjected to electrical insulation treatment so that a current should not flow to the substrate 10 during working of the capacitor.

When the substrate 10 is, for example, a Si single crystal substrate, it is preferable that an insulating film be formed on the surface of the substrate 10. As long as insulation between the substrate 10 and the lower electrode 30 is sufficiently secured, the material to form the insulating film and the thickness of the film are not particularly limited. Examples of the materials to form the insulating film include SiO₂, Al₂O₃ and Si₃Nₓ. It is preferable that the thickness of the insulating film be 0.01 μm or more. It is preferable that the insulting film be provided on the adhesive film 20 side (lower electrode 30 side) of the substrate 10. The insulating film can be formed by a known deposition method such as thermal oxidation method or CVD (chemical vapor deposition) method.

(Adhesive Film)

The adhesive film 20 is provided between the substrate 10 and the lower electrode 30, and improves adhesion between the substrate 10 and the lower electrode 30. The material of the adhesive film 20 is not particularly restricted as long as it is a material capable of sufficiently securing adhesion between the substrate 10 and the lower electrode 30. For example, when the lower electrode 30 is a Cu film, the adhesive film 20 can be a Cr film, and when the lower electrode 30 is a Pt film, the adhesive film 20 can be a Ti film. The thickness of the adhesive film 20 can be set at, for example, 5 to 50 nm.

(Lower Electrode)

On the substrate 10, the lower electrode 30 is formed in a thin film form through the adhesive film 20. The lower electrode 30 is an electrode that interposes the dielectric film 40 together with the upper electrode 50 to allow the resulting product to function as a capacitor. The material to form the lower electrode 30 is not particularly restricted as long as it is a material having conductivity. Examples of the materials include metals, such as Pt, Ru, Rh, Pd, Ir, Au, Ag, Cu and Ni, alloys thereof, and conductive oxides.

The thickness of the lower electrode 30 is not particularly restricted as long as it is a thickness of such an extent that the resulting electrode functions as an electrode. It is preferable that the thickness of the lower electrode 30 be 10 nm or more, and from the viewpoint of thinning, it is preferable that the thickness be 300 nm or less.

(Dielectric Film)

The dielectric film 40 is the aforesaid dielectric film. As previously described, the thickness of the dielectric film 40 can be set at 10 nm to 2000 nm, and is preferably 50 nm to 1000 nm. The thickness of the dielectric film 40 can be measured by excavating the thin film capacitor 100 comprising the dielectric film 40 by a FIB (focused ion beam) processing device and observing the resulting section by SEM (scanning type electron microscope).

(Upper Electrode)

On the upper surface of the dielectric film 40, the upper electrode 50 is formed in a thin film form. The upper electrode 50 is an electrode that interposes the dielectric film 40 together with the aforesaid lower electrode 30 to allow the resulting product to function as a capacitor.

The material of the upper electrode 50 is not particularly restricted as long as it is a material having conductivity, similarly to the lower electrode 30. Examples of the materials include metals, such as Pt, Ru, Rh, Pd, Ir, Au, Ag, Cu and Ni, alloys thereof, and conductive oxides, and the material of the upper electrode may be the same as or may be different from the material of the lower electrode 30. The thickness of the upper electrode 50 can be set at the same as that of the lower electrode 30.

The thin film capacitor 100 may have a protective film 70 that covers side surfaces, etc. of the dielectric film 40 to shield the dielectric film 40 from the external atmosphere. Examples of materials of the protective film include resins such as epoxy.

The shape of the thin film capacitor is not particularly restricted, but in usual, the capacitor is made to have a rectangular parallelepiped shape when seen from the thickness direction. The dimensions thereof are not particularly restricted either, and the thickness and the length only need to be set at appropriate dimensions according to the use application.

The lower electrode 30, the dielectric film 40 and the upper electrode 50 form a capacitor section 60. When the lower electrode 30 and the upper electrode 50 are connected to an external circuit and a voltage is applied between the electrodes, the dielectric film 40 shows a prescribed capacitance, and the thin film capacitor exhibits a function as a capacitor. In particular, the present embodiment uses the aforesaid dielectric film 40, and therefore, high DC bias characteristics and high withstand voltage are compatible with each other.

(Process for Producing Thin Film Capacitor)

Next, one example of the process for producing the thin film capacitor 100 shown in FIG. 1 will be described.

First, the substrate 10 is provided, and on the substrate 10, the adhesive film 20 and the lower electrode 30 are formed by known deposition methods such as a sputtering method.

After formation of the lower electrode 30, heat treatment may be carried out for the purpose of improving adhesion between the adhesive film 20 and the lower electrode 30 and improving stability of the lower electrode 30. As the heat treatment conditions, for example, the temperature rise rate is preferably 10° C./min to 2000° C./min, more preferably 100° C./min to 1000° C./min. In the heat treatment, the retention temperature is preferably 400° C. to 800° C., and the retention time thereof is preferably 0.1 hours to 4.0 hours. When the heat treatment conditions are out of the above ranges, adhesion failure between the adhesive film 20 and the lower electrode 30 and irregularities of the surface of the lower electrode 30 easily occur. As a result, lowering of dielectric characteristics of the dielectric film 40 is liable to occur.

Subsequently, on the lower electrode 30, the dielectric film 40 is formed by the aforesaid process. The aforesaid annealing can be carried out when necessary.

Next, on the dielectric film 40 formed, the upper electrode 50 is formed using a known deposition method such as a sputtering method.

Through the above steps, a thin film capacitor 100 in which the capacitor section (lower electrode 30, dielectric film 40 and upper electrode 50) 60 is formed on the substrate 10 via the adhesive film 20, as shown in FIG. 1, is obtained. The protective film 70 to protect the dielectric film 40 only needs to be formed by a known film-forming method so as to cover at least part of the dielectric film 40 exposed to the outside.

### Modification Examples

The embodiment of the present invention is described hereinbefore, but the present invention is in no way limited to the above embodiment, and modifications may be made in various embodiments within the scope of the present invention.

For example, between the lower electrode 30 and the upper electrode 50, a dielectric film of a material different from that of the dielectric film 40 may be further provided. For example, by forming a stacked structure of an amorphous film or a crystal film of Si₃Nₓ, SiOₓ, Al₂Oₓ, ZrOₓ, Ta₂Oₓ or the like and the aforesaid dielectric film 40, it becomes possible to control an impedance of the whole of a plurality of dielectric films and a change of dielectric constant with temperature.

In the aforesaid embodiment, the adhesive film 20 is formed in order to improve adhesion between the substrate 10 and the lower electrode 30, but when adhesion between the substrate 10 and the lower electrode 30 can be sufficiently secured, the adhesive film 20 can be omitted. When a metal such as Cu or Pt, an alloy thereof, an oxide conductive material or the like, each being employable as an electrode, is used as a material for forming the substrate 10, the adhesive film 20 and the lower electrode 30 can be omitted.

The dielectric film according to the present embodiment can be utilized not only for the capacitor but also for an electronic circuit board and an electronic component such as a piezoelectric element.

(Electronic Circuit Board)

The electronic circuit board according to the present embodiment comprise the above dielectric film. The electronic circuit board may comprise an electronic component such as a thin film capacitor comprising the above dielectric film. The electronic component such as a thin film capacitor may be installed on the surface of the electronic circuit board. The electronic component such as a thin film capacitor may be embedded in the electronic circuit board.

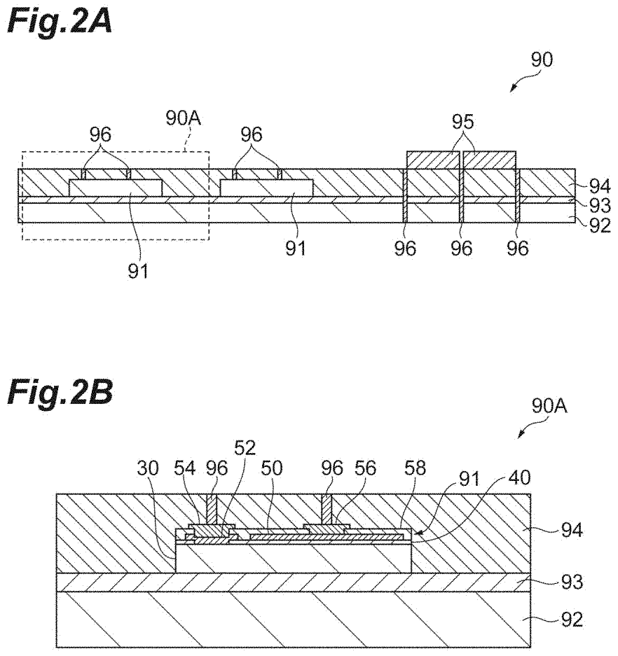

One example of the electronic circuit board is shown in FIG. 2A and FIG. 2B. The electronic circuit board 90 may comprise an epoxy-based resin substrate 92, a resin layer 93 covering the epoxy-based resin substrate 92, a thin film capacitor 91 provided on the resin layer 93, an insulating coating layer 94 covering the resin layer 93 and the thin film capacitor 91, an electronic component 95 provided on the insulating coating layer 94, and a plurality of metal wirings 96. At least part of the metal wirings 96 may be drawn out onto the surface of the epoxy-based resin substrate 92 or the insulating coating layer 94. At least part of the metal wirings 96 may be connected to extraction electrodes 54, 56 of the thin film capacitor 91, or the electronic component 95. At least part of the metal wirings 96 may penetrate the electronic circuit board 90 in a direction from the front surface toward the back surface of the electronic circuit board 90.

As shown in FIG. 2B, the thin film capacitor 91 according to the present embodiment may comprise a lower electrode 30, a dielectric film 40 provided on the surface of the lower electrode 30, an upper electrode 50 provided on part of the upper surface of the dielectric film 40, a through electrode 52 penetrating the other part of the dielectric film 40 and directly provided on the surface of the lower electrode 30, an insulating resin layer 58 covering the upper electrode 50, the dielectric film 40 and the through electrode 52, an extraction electrode 54 penetrating the insulating resin layer 58 and directly provided on the surface of the through electrode 52, and an extraction electrode 56 penetrating the insulating resin layer 58 and directly provided on the surface of the upper electrode 50.

The electronic circuit board 90 may be produced by the following procedure. First, the surface of the epoxy-based resin substrate 92 is covered with an uncured resin layer. The uncured resin layer is a precursor of the resin layer 93. The thin film capacitor 91 is installed on the surface of the uncured resin layer in such a manner that the base electrode of the thin film capacitor 91 faces the uncured resin layer. By covering the uncured resin layer and the thin film capacitor 91 with the insulating coating layer 94, the thin film capacitor 91 is interposed between the epoxy-based resin substrate 92 and the insulating coating layer 94. Through thermosetting of the uncured resin layer, the resin layer 93 is formed. Through hot pressing, the insulating coating layer 94 is pressure bonded to the epoxy-based resin substrate 92, the thin film capacitor 91 and the resin layer 93. A plurality of through-holes penetrating this stacked board are formed. The metal wiring 96 is formed in each through-hole. After formation of the metal wirings 96, the electronic component 95 is installed on the surface of the insulating coating layer 94. By the above process, the electronic circuit board 90 in which the thin film capacitor 91 is embedded is obtained. Each of the metal wirings 96 may be formed of a conductor such as Cu. The uncured resin layer may be a thermosetting resin (e.g., epoxy resin) of the B stage. The thermosetting resin of the B stage is not completely cured at room temperature, and it is completely cured by heating. The insulating coating layer 94 may be formed of an epoxy-based resin, a polytetrafluoroethylene-based resin or a polyimide-based resin.

### Examples

The present invention will be described in more detail using examples and comparative examples. However, the present invention is not limited to the following examples.

### Examples, Comparative Examples

First, a sputtering target necessary for forming a dielectric film was prepared in the following manner through a solid phase method.

As raw material powders for target preparation, powders of barium carbonate, strontium carbonate, calcium carbonate, titanium oxide, bismuth oxide, sodium carbonate, potassium carbonate, lanthanum hydroxide, cerium oxide, praseodymium oxide, neodymium oxide, samarium oxide, europium oxide, gadolinium oxide, terbium oxide, dysprosium oxide, holmium oxide, ytterbium oxide and yttrium oxide were provided. These powders were each weighed in such a manner that with regard to the first embodiment, the numbers of atoms of the metals formed compositions shown in Table 1 and Table 2, and with regard to the second embodiment, the numbers of atoms of the metals formed compositions shown in Table 3 and Table 4.

In a ball mill, wet mixing of the weighed raw material powders for target preparation was carried out for 20 hours using water as a solvent. The resulting mixed powder slurry was dried at 100° C., thereby obtaining a mixed powder. The resulting mixed powder was pressed using a press machine, thereby obtaining a compact. As the compacting conditions, the pressure was set at 100 MPa, the temperature was set at 25° C., and the pressing time was set at 3 minutes.

Thereafter, the resulting compact was fired, thereby obtaining a fired product. As the firing conditions, the retention temperature was set at 1100° C., the retention time at the temperature was set at 5 hours, and the atmosphere was an air atmosphere.

The resulting fired product was processed to a diameter of 80 mm and a thickness of 5 mm by the use of a surface grinding machine and a cylindrical grinding machine, thereby obtaining a sputtering target for forming a dielectric film.

Subsequently, a Si wafer with a thickness of 500 μm was subjected to heat treatment in a dry atmosphere of an oxidizing gas to form a SiO₂ film with a thickness of 500 nm on the wafer surface, and the film was taken as a substrate. On the surface of this substrate, a Cr thin film as an adhesive film was first formed by a sputtering method in such a manner that the thickness became 20 nm. On the Cr thin film formed above, a Pt thin film was formed by a sputtering method in such a manner that the thickness became 100 nm, and the film was taken as a lower electrode.

Next, on the lower electrode, a dielectric film was formed in a thickness of 300 nm by a sputtering method using the sputtering target prepared above. As the sputtering conditions, the atmosphere was Ar/O₂=3/1, the pressure was set at 1.0 Pa, the radio frequency power was set at 200 W, and the substrate temperature was set at 100° C. After the dielectric film was formed, the dielectric film was subjected to rapid thermal anneal (RTA) at a temperature rise rate of 900° C./min in an air atmosphere under the conditions of 900° C. and one minute.

Next, on the resulting dielectric film, a Pt thin film was formed by a sputtering method using a mask in such a manner that the diameter became 200 μm and the thickness became 100 nm, and the film was taken as an upper electrode. Through the above steps, a thin film capacitor having constitution shown in FIG. 1 was obtained.

The crystal structure of the dielectric film was measured and analyzed by an X-ray diffraction method using an XRD measuring device (Rigaku Corporation, SmartLab). As a result, the dielectric film was confirmed to have a perovskite-type crystal structure.

The composition of the dielectric film was analyzed using XRF (X-ray fluorescence analysis), and was continued to agree with the composition described in Table 1.

With regard to all the resulting thin film capacitors, dielectric constants during DC bias application were measured by the method described below.

(Dielectric Constant)

The dielectric constant (relative permittivity without unit) during DC bias application was calculated from a capacitance, an effective electrode area, a distance between electrodes and a dielectric constant of vacuum which were measured using a digital LCR meter (Hewlett-Packard Company, 4284A) under the conditions of room temperature of 25° C., a frequency of 1 kHz, an input signal level (measuring voltage) of 1.0 Vrms while applying a DC bias of 10 V/μm to the thin film capacitor in its thickness direction. For a dielectric film, a higher dielectric constant during DC bias application is preferable, and a sample whose dielectric constant during DC bias application was 600 or more was judged to be good. The results are set forth in Table 1.

For reference, dielectric constants were also measured without applying a DC bias. The measurement conditions were the same except that a DC bias was not applied. The results are set forth in Table 1.

(Withstand Voltage Characteristics)

When a DC voltage was applied to a pair of electrodes of the thin film capacitor at a voltage boosting rate of 1 V/sec, the voltage starting from 0 V, a voltage at which a current of 10 mA or more flowed between the electrodes was taken as a breakdown voltage. In the present example, the above evaluation was carried out on 10 sample pieces, and a sample with an average of breakdown voltage of 40 kV/mm or more was judged to be good.

TABLE 1

| | | | | | | | | Number of atoms of Ln | | | |
|---|---|---|---|---|---|---|---|---|---|---|---|
| | | | | | | | | based on total of numbers | | | Withstand |
| | Ratio of number of atoms | | | | | | | of atoms of | Dielectric | Dielectric constant | voltage |
| | Bi | Na | Ba | Ca | Ti | X_{Bi}/(X_{Ba} + X_{Ca}) | Ln | Bi + Na + Ba + Ca (%) | constant at 0 V | at 10 V/μm | (V/μm) |
| Ex. A1 | 45 | 45 | 10 | | 100 | 4.500 | La | 5 | 730 | 610 | 41 |
| Ex. A2 | 35 | 35 | 30 | | 100 | 1.167 | La | 5 | 760 | 650 | 43 |
| Ex. A3 | 25 | 25 | 50 | | 100 | 0.500 | La | 5 | 770 | 670 | 45 |
| Ex. A4 | 15 | 15 | 70 | | 100 | 0.214 | La | 5 | 800 | 650 | 48 |
| Comp. Ex. A1 | 12.5 | 12.5 | 75 | | 100 | 0.167 | La | 5 | 900 | 510 | 45 |
| Comp. Ex. A2 | 47.5 | 47.5 | 5 | | 100 | 9.500 | La | 5 | 700 | 550 | 30 |
| Ex. A5 | 45 | 45 | | 10 | 100 | 4.500 | La | 5 | 670 | 620 | 42 |
| Ex. A6 | 35 | 35 | | 30 | 100 | 1.167 | La | 5 | 660 | 630 | 43 |
| Ex. A7 | 25 | 25 | | 50 | 100 | 0.500 | La | 5 | 650 | 620 | 47 |
| Ex. A8 | 15 | 15 | | 70 | 100 | 0.214 | La | 5 | 660 | 610 | 48 |
| Comp. Ex. A3 | 12.5 | 12.5 | | 75 | 100 | 0.167 | La | 5 | 540 | 430 | 45 |
| Comp. Ex. A4 | 47.5 | 47.5 | | 5 | 100 | 9.500 | La | 5 | 690 | 520 | 30 |
| Ex. A9 | 25 | 25 | 25 | 25 | 100 | 0.500 | La | 5 | 720 | 650 | 44 |
| Ex. A10 | 35 | 35 | 30 | | 100 | 1.167 | La | 1 | 740 | 670 | 40 |
| Ex. A11 | 35 | 35 | 30 | | 100 | 1.167 | La | 15 | 720 | 670 | 48 |
| Comp. Ex. A5 | 35 | 35 | 30 | | 100 | 1.167 | — | 0 | 760 | 630 | 35 |

TABLE 2

| | | | | | | | Number of atoms of Ln | | | |
|---|---|---|---|---|---|---|---|---|---|---|
| | | | | | | | based on total of numbers | | | Withstand |
| Ratio of number of atoms | | | | | | | of atoms of | Dielectric | Dielectric constant | voltage |
| Bi | Na | Ba | Ca | Ti | X_{Bi}/(X_{Ba} + X_{Ca}) | Ln | Bi + Na + Ba + Ca (%) | constant at 0 V | at 10 V/μm | (V/μm) |

| | | | | | | | | | | |
|---|---|---|---|---|---|---|---|---|---|---|
| Ex. A11 | 35 | 35 | 30 | 100 | 1.167 | Ce | 5 | 700 | 640 | 47 |
| Ex. A12 | 35 | 35 | 30 | 100 | 1.167 | Pr | 5 | 770 | 650 | 42 |
| Ex. A13 | 35 | 35 | 30 | 100 | 1.167 | Nd | 5 | 770 | 670 | 43 |
| Ex. A14 | 35 | 35 | 30 | 100 | 1.167 | Sm | 5 | 710 | 630 | 41 |
| Ex. A15 | 35 | 35 | 30 | 100 | 1.167 | Eu | 5 | 700 | 660 | 42 |
| Ex. A16 | 35 | 35 | 30 | 100 | 1.167 | Gd | 5 | 710 | 610 | 45 |
| Ex. A17 | 35 | 35 | 30 | 100 | 1.167 | Tb | 5 | 730 | 610 | 48 |
| Ex. A18 | 35 | 35 | 30 | 100 | 1.167 | Dy | 5 | 750 | 680 | 42 |
| Ex. A19 | 35 | 35 | 30 | 100 | 1.167 | Ho | 5 | 760 | 680 | 45 |
| Ex. A20 | 35 | 35 | 30 | 100 | 1.167 | Yb | 5 | 730 | 620 | 45 |
| Ex. A21 | 35 | 35 | 30 | 100 | 1.167 | Y | 5 | 720 | 610 | 42 |

TABLE 3

| | | | | | | | | | Number of atoms of Ln | | | |
|---|---|---|---|---|---|---|---|---|---|---|---|---|
| | | | | | | | | | based on total of numbers of | Dielectric | Dielectric | Withstand |
| | Ratio of number of atoms | | | | | | | | atoms of Bi + K + Ba + Sr + Ca | constant at | constant at | voltage |
| | Bi | K | Ba | Sr | Ca | Ti | X_{Bi}/(X_{Ba} + X_{Sr} + X_{Ca}) | Ln | (%) | 0 V | 10 V/μm | (V/μm) |
| Ex. B1 | 45 | 45 | 10 | | | 100 | 4.500 | La | 5 | 730 | 610 | 41 |
| Ex. B2 | 35 | 35 | 30 | | | 100 | 1.167 | La | 5 | 760 | 650 | 43 |
| Ex. B3 | 25 | 25 | 50 | | | 100 | 0.500 | La | 5 | 770 | 670 | 45 |
| Ex. B4 | 15 | 15 | 70 | | | 100 | 0.214 | La | 5 | 800 | 650 | 48 |
| Comp. Ex. B1 | 47.5 | 47.5 | 5 | | | 100 | 9.500 | La | 5 | 700 | 550 | 30 |
| Comp. Ex. B2 | 12.5 | 12.5 | 75 | | | 100 | 0.167 | La | 5 | 900 | 510 | 45 |
| Ex. B5 | 45 | 45 | | 10 | | 100 | 4.500 | La | 5 | 750 | 610 | 43 |
| Ex. B6 | 35 | 35 | | 30 | | 100 | 1.167 | La | 5 | 770 | 630 | 43 |
| Ex. B7 | 25 | 25 | | 50 | | 100 | 0.500 | La | 5 | 780 | 650 | 42 |
| Ex. B8 | 15 | 15 | | 70 | | 100 | 0.214 | La | 5 | 690 | 650 | 45 |
| Comp. Ex. B3 | 47.5 | 47.5 | | 5 | | 100 | 9.500 | La | 5 | 750 | 520 | 30 |
| Comp. Ex. B4 | 12.5 | 12.5 | | 75 | | 100 | 0.167 | La | 5 | 650 | 550 | 43 |
| Ex. B9 | 45 | 45 | | | 10 | 100 | 4.500 | La | 5 | 670 | 620 | 42 |
| Ex. B10 | 35 | 35 | | | 30 | 100 | 1.167 | La | 5 | 660 | 630 | 43 |
| Ex. B11 | 25 | 25 | | | 50 | 100 | 0.500 | La | 5 | 650 | 620 | 47 |
| Ex. B12 | 15 | 15 | | | 70 | 100 | 0.214 | La | 5 | 660 | 610 | 48 |
| Comp. Ex. B5 | 47.5 | 47.5 | | | 5 | 100 | 9.500 | La | 5 | 690 | 520 | 30 |
| Comp. Ex. B6 | 12.5 | 12.5 | | | 75 | 100 | 0.167 | La | 5 | 540 | 430 | 45 |
| Ex. B13 | 25 | 25 | | 50 | | 100 | 0.500 | La | 1 | 740 | 670 | 41 |
| Ex. B14 | 25 | 25 | | 50 | | 100 | 0.500 | La | 15 | 720 | 670 | 49 |
| Comp. Ex. B7 | 25 | 25 | | 50 | | 100 | 0.500 | — | 0 | 720 | 620 | 33 |

TABLE 4

| | | | | | | | | | Number of atoms of Ln | | | |
|---|---|---|---|---|---|---|---|---|---|---|---|---|
| | | | | | | | | | based on total of numbers of | Dielectric | Dielectric | Withstand |
| | Ratio of number of atoms | | | | | | | | atoms of Bi + K + Ba + Sr + Ca | constant at | constant at | voltage |
| | Bi | K | Ba | Sr | Ca | Ti | X_{Bi}/(X_{Ba} + X_{Sr} + X_{Ca}) | Ln | (%) | 0 V | 10 V/μm | (V/μm) |
| Ex. B15 | 25 | 25 | | 50 | | 100 | 0.500 | Ce | 5 | 700 | 640 | 47 |
| Ex. B16 | 25 | 25 | | 50 | | 100 | 0.500 | Pr | 5 | 770 | 650 | 42 |
| Ex. B17 | 25 | 25 | | 50 | | 100 | 0.500 | Nd | 5 | 770 | 670 | 43 |
| Ex. B18 | 25 | 25 | | 50 | | 100 | 0.500 | Sm | 5 | 710 | 630 | 41 |
| Ex. B19 | 25 | 25 | | 50 | | 100 | 0.500 | Eu | 5 | 700 | 660 | 42 |
| Ex. B20 | 25 | 25 | | 50 | | 100 | 0.500 | Gd | 5 | 710 | 610 | 45 |
| Ex. B21 | 25 | 25 | | 50 | | 100 | 0.500 | Tb | 5 | 730 | 610 | 48 |
| Ex. B22 | 25 | 25 | | 50 | | 100 | 0.500 | Dy | 5 | 750 | 680 | 42 |
| Ex. B23 | 25 | 25 | | 50 | | 100 | 0.500 | Ho | 5 | 760 | 680 | 45 |
| Ex. B24 | 25 | 25 | | 50 | | 100 | 0.500 | Yb | 5 | 730 | 620 | 45 |
| Ex. B25 | 25 | 25 | | 50 | | 100 | 0.500 | Y | 5 | 720 | 610 | 42 |
| Ex. B26 | 25 | 25 | 25 | 25 | | 100 | 0.500 | La | 5 | 770 | 660 | 42 |
| Ex. B27 | 25 | 25 | 25 | | 25 | 100 | 0.500 | La | 5 | 730 | 650 | 44 |
| Ex. B28 | 25 | 25 | | 25 | 25 | 100 | 0.500 | La | 5 | 740 | 630 | 45 |
| Ex. B29 | 35 | 35 | 10 | 10 | 10 | 100 | 1.167 | La | 5 | 710 | 620 | 43 |

From Tables 1 to 4, it was able to be confirmed that the dielectric constants of the thin film capacitors according to the examples during DC bias application were high, and the withstand voltage characteristics thereof were also high.

### REFERENCE SIGNS LIST

10: substrate, 20: adhesive film, 30: lower electrode, 40: dielectric film, 50: upper electrode, 90: electronic circuit board, 91, 100: thin film capacitor

What is claimed is:

1. A dielectric film comprising an oxide having a perovskite structure, wherein
the oxide comprises:
(1) Bi, Na and Ti;
(2) at least one of Ba and Ca; and
(3) at least one element Ln selected from the group consisting of La, Ce, Pr, Nd, Sm, Eu, Gd, Tb, Dy, Ho, Yb and Y, and
when ratios of the numbers of atoms of Bi, Ba and Ca to the total of the numbers of atoms of Bi, Na, Ba and Ca in the oxide are represented by X_{Bi}, X_{Ba} and X_{Ca}, respectively, the ratios satisfy
0.2≤X_{Bi}/(X_{Ba}+X_{Ca})≤5.

2. The dielectric film according to claim 1, wherein when a ratio of the number of atoms of Na to the total of the numbers of atoms of Bi, Na, Ba and Ca in the oxide is represented by X_{Na}, the ratio satisfies
0.9X_{Bi}≤X_{Na}≤1.1X_{Bi}.

3. The dielectric film according to claim 1, wherein a ratio of the number of atoms of Ti to the total of the numbers of atoms of Bi, Na, Ba and Ca in the oxide is 80% or more and 120% or less.

4. The dielectric film according to claim 1, wherein a ratio of the number of atoms of Ln to the total of the numbers of atoms of Bi, Na, Ba and Ca in the oxide is 0.5 to 20%.

5. A dielectric film comprising an oxide having a perovskite structure, wherein
the oxide comprises:
(1) Bi, K and Ti;
(2) at least one selected from the group consisting of Ba, Sr and Ca; and
(3) at least one element Ln selected from the group consisting of La, Ce, Pr, Nd, Sm, Eu, Gd, Tb, Dy, Ho, Yb and Y, and
when ratios of the numbers of atoms of Bi, Ba, Sr and Ca to the total of the numbers of atoms of Bi, K, Ba, Sr and Ca in the oxide are represented by X_{Bi}, X_{Ba}, Xₛᵣ and X_{Ca}, respectively, the ratios satisfy
0.2≤X_{Bi}/(X_{Ba}+X_{Sr}+X_{Ca})≤5.

6. The dielectric film according to claim 5, wherein when a ratio of the number of atoms of K to the total of the numbers of atoms of Bi, K, Ba, Sr and Ca in the oxide is represented by X_{K}, the ratio satisfies
0.9X_{Bi}≤X_{K}≤1.1X_{Bi}.

7. The dielectric film according to claim 5, wherein a ratio of the number of atoms of Ti to the total of the numbers of atoms of Bi, K, Ba, Sr and Ca in the oxide is 80% or more and 120% or less.

8. The dielectric film according to claim 5, wherein a ratio of the number of atoms of Ln to the total of the numbers of atoms of Bi, K, Ba, Sr and Ca in the oxide is 0.5 to 20%.

9. An electronic component comprising the dielectric film according to claim 1.

10. A thin film capacitor comprising the dielectric film according to claim 1.

11. An electronic circuit board comprising the dielectric film according to claim 1.

12. An electronic circuit board comprising the electronic component according to claim 9.

13. An electronic circuit board comprising the thin film capacitor according to claim 10.

14. An electronic component comprising the dielectric film according to claim 5.

15. A thin film capacitor comprising the dielectric film according to claim 5.

16. An electronic circuit board comprising the dielectric film according to claim 5.

17. An electronic circuit board comprising the electronic component according to claim 14.

18. An electronic circuit board comprising the thin film capacitor according to claim 15.
